(19) United States
(12) Patent Application Publication
(10) Pub. No.: US 2005/0213399 A1
(43) Pub. Date: Sep. 29, 2005

(54) Method and apparatus to write data

(76) Inventors: Patricia J. Hoover, Austin, TX (US); Mark N. Fullerton, Austin, TX (US)

Correspondence Address: Anthony M. Martinez;Intel Corporation, 2200 Mission College Blvd., Santa Clara, CA, 95052, US

(21) Appl. No.: 10/812,661

(22) Filed: Mar. 29, 2004

(51) Int. Cl. G11C 11/34; G11C 16/06; G11C 7/00

(52) U.S. Cl. 365/191

(57) ABSTRACT

Briefly, in accordance with an embodiment of the invention, a method and apparatus to write data is provided. The apparatus may include a circuit to deassert a chip select signal to latch data in a first memory after asserting a write enable signal and prior to deasserting the write enable signal, wherein the chip select signal is coupled to the first memory and the write enable signal is coupled to both the first memory and a second memory. The method may include asserting a chip select signal after asserting of a write enable signal and then deasserting the chip select signal to latch the data in a memory, wherein the deasserting of the chip select signal occurs prior to the deasserting of the write enable signal. Other embodiments are described and claimed.

### BACKGROUND

One type of memory for storing data and/or code is a flash electrically erasable programmable read-only memory (“flash EEPROM” or “flash memory”). Once programmed, the flash memory may retain its data until the memory is erased. Electrical erasure of the flash memory may include erasing the contents of the memory of the device in one relatively rapid operation. The flash memory may then be programmed with new code or data.

A flash memory may be controlled using commands and control signals such as, for example, a chip select (CS) signal and a write enable signal (WE). The commands may include a read, program or write, and erase commands. The chip enable signal may also be referred to as a chip enable (CE) signal.

Glitch or noise signals may occur on the bus that may cause the WE and CS signals to become asserted inadvertently. This may cause the flash memory to initiate an undesirable or unwanted write operation by latching in unwanted or invalid write commands in the flash memory.

Thus, there is a continuing need for alternate ways to write data to a memory.

### BRIEF DESCRIPTION OF THE DRAWINGS

The subject matter regarded as the invention is particularly pointed out and distinctly claimed in the concluding portion of the specification. The present invention, however, both as to organization and method of operation, together with objects, features, and advantages thereof, may best be understood by reference to the following detailed description when read with the accompanying drawings in which:

FIG. 1 is a block diagram illustrating a computing system in accordance with an embodiment of the present invention;

FIG. 2 is a timing diagram illustrating a write operation in accordance with an embodiment of the present invention;

FIG. 3 is a block diagram illustrating a computing system in accordance with an embodiment of the present invention;

FIG. 4 is a block diagram illustrating an implementation of the computing system of FIG. 3 in accordance with an embodiment of the present invention;

FIG. 5 is a timing diagram illustrating a write operation;

FIG. 6 is a timing diagram illustrating a write operation in accordance with an embodiment of the present invention; and

FIG. 7 is a block diagram illustrating a wireless device in accordance with an embodiment of the present invention.

It will be appreciated that for simplicity and clarity of illustration, elements illustrated in the figures have not necessarily been drawn to scale. For example, the dimensions of some of the elements are exaggerated relative to other elements for clarity. Further, where considered appropriate, reference numerals have been repeated among the figures to indicate corresponding or analogous elements.

### DETAILED DESCRIPTION

In the following detailed description, numerous specific details are set forth in order to provide a thorough understanding of the present invention. However, it will be understood by those skilled in the art that the present invention may be practiced without these specific details. In other instances, well-known methods, procedures, components and circuits have not been described in detail so as not to obscure the present invention.

In the following description and claims, the terms “include” and “comprise,” along with their derivatives, may be used, and are intended to be treated as synonyms for each other. In addition, in the following description and claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still co-operate or interact with each other.

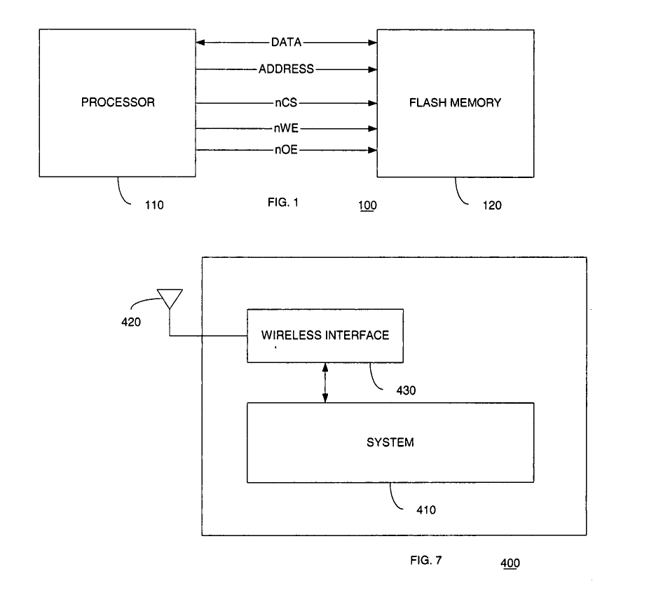

FIG. 1 is a block diagram illustrating a computing system 100 in which embodiments of the present invention may be used. System 100 may include a processor 110 and a flash memory 120 coupled to processor 110.

Although not shown, system 100 may include other components such as, for example, more processors, input/output (I/O) devices, storage devices, or other memories such as, for example, a cache memory. In addition, system 100 may include other peripheral interfaces or controllers such as, for example, a liquid crystal display (LCD) controller or a camera interface. However, for simplicity these additional components have not been shown.

Flash memory 120 may be a NAND or NOR type of flash memory, and may be a single bit per cell or multiple bits per cell memory. Flash memory 120 may store software instructions and/or data. The terms “data” or “information” may be used to refer to either data, instructions, or code. Processor 110 may include logic to execute software instructions and may also be referred to as a core, a controller or a processing unit. Processor 110 may also include a memory controller or a circuit or circuitry such as, for example, digital logic to control memory accesses to flash memory 120.

In one embodiment, processor 110 may include a write state machine (WSM) (not shown) to manage erasing of, and writing to, flash memory 120. The WSM may generate the commands and control signals to write to flash memory 120. For example, control signals nCS, nWE, and nOE may be generated by the WSM of processor 110. The “n” prefix may indicate that these signals are active low signals. In other words, these signals are asserted when they are at a relatively “low” voltage level of for example, about zero volts, and are deasserted when they are at a relatively “high” voltage level of, for example, about two volts.

As discussed above, CS and WE are chip select and write enable signals, respectively. OE is an output enable signal that may be the output control signal for flash memory 120. In one example, when OE is deasserted, the device outputs of flash memory 120 may be disabled and placed in a high impedance (high-z) state. During a write operation, processor 110 may provide or send several bits or bytes of data and an address to flash memory 120, wherein the address is the location in flash memory 120 where the data is to be written. The nCS, nWE, and nOE signals may be respectively coupled to a chip select pin, a write enable pin, and an output enable pin of flash memory 120.

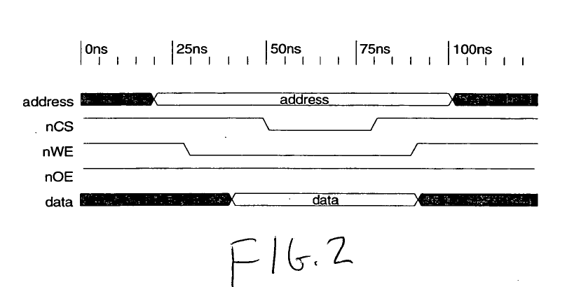

Turning to FIG. 2, shown is a timing diagram illustrating a write operation to flash memory 120 in accordance with an embodiment of the present invention. In this embodiment, all write operations may be asynchronous, so that the clock (not shown) to the memory may be ignored. To perform a write operation, both nCS and nWE may be asserted while nOE may be deasserted.

As is illustrated in FIG. 2, in one embodiment writing data to flash memory 120 may begin with transmitting or sending the write address to flash memory 120. Next, the nWE signal may be asserted and the nCS signal may be asserted after the asserting of the nWE signal. Then, the nCS signal may be deasserted to latch the data and the address in flash memory 120, wherein the deasserting of the nCS signal occurs after the asserting of the nWE signal. Next, the nWE signal may be deasserted after the deasserting of the nCS signal.

In this embodiment, the address and data are latched in flash memory 120 on the rising edge of the nCS signal, i.e., the address and data are latched in flash memory 120 on the deasserting of the nCS signal. The data and address may be sent to flash memory 120 anytime prior to the deasserting of the nCS signal. During the entire write operation, nOE may be deasserted.

Although nWE is illustrated as being asserted prior to the asserting of nCS, this is not a limitation of the present invention. In an alternate embodiment, nCS may be asserted prior to nWE. In addition, although the CS and WE signals are illustrated as active low, in an alternate embodiment, the CS and WE signals may be active high signals and the address and data may be latched on a falling edge of CS rather than a rising edge as is illustrated in FIG. 2. It should be pointed out that the times shown at the top of FIG. 2 are only one example, and the present invention is not limited in this respect.

If commands are used, a write operation may include two back-to-back writes, wherein the data and address sent to flash memory 120 during the first write may include the command and the data and address sent to flash memory 120 during the second write may include the data to be written.

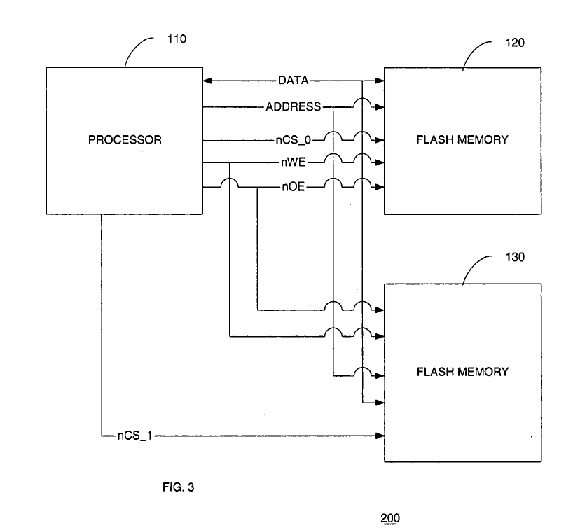

Turning to FIG. 3, shown is a block diagram illustrating a computing system 200 in accordance with an embodiment of the present invention. System 200 may include processor 110, flash memory 120, and a flash memory 130. In this embodiment, the nWE and nOE signals are shared between multiple flash memories, i.e., are shared between flash memory 120 and flash memory 130. In other words, the nWE signal is coupled to at least two memories, e.g., the nWE signal may be coupled to both the write enable pin of flash memory 120 and to the write enable pin of flash memory 130. Similarly, the nOE signal is coupled to at least two memories, e.g., the nOE signal may be coupled to both the output enable pin of flash memory 120 and to the output enable pin of flash memory 130. Sharing control signals may reduce the number of pins on processor 110.

Dedicated CS signals may be used in computing system 200, e.g., a dedicated nCS_0 signal may be coupled to the chip select pin of flash memory 120 and a dedicated nCS_1 signal may be coupled to the chip select pin of flash memory 130.

As an example, one problem that may occur by sharing signals is if flash memory 120 is physically close to processor 110 (e.g., if flash memory 120 is a discrete die stacked on the processor 110 die), and flash memory 130 is farther away from processor 110 (e.g., the flash memory 130 die is not stacked on processor 110 die), the shared control signals may experience some signal integrity issues, e.g. reflection on the signals such that what is seen is not predictable and erroneous edges may occur on the signals that may cause inadvertent writes. To overcome this problem, writing to flash memories 120 and 130 may be accomplished using the method illustrated in FIG. 2. Specifically, in one embodiment, during a write operation, the data and address sent to either flash memory 120 or 130 is latched in the memory on the deassertion of the dedicated chip select signal rather than on the deassertion of the shared write enable signal. In other words, the write to a flash memory (e.g., 120 or 130) of system 200 may occur on the rising edge of the dedicated chip select signal (e.g., nCS_0 or nCS_1) rather than on the rising edge of the shared write enable signal (e.g., nWE). This may allow the dedicated chip select signal to be the controlling signal during a write operation and may allow for any reflection on the shared write enable signal to not affect the system.

One solution to the problem of reflection of signals may be to include a terminator circuit or matching circuit near an end of the wire. However, including a matching or terminator circuit may increase power consumption.

Although system 200 is illustrated as having only two flash memories, this is not a limitation of the present invention. In other embodiments, system 200 may have more than two memories. Further, although memories 120 and 130 are illustrated above as nonvolatile flash memories, this is not a limitation of the present invention. In other embodiments, memories 120 and 130 may be volatiles memories such as, for example, a static random access memory (SRAM) or a dynamic random access memory (DRAM) that may share write enable signals. In addition, in another embodiment, flash memories 120 and 130 may be another type of nonvolatile memory such as, for example, a read only memory (ROM).

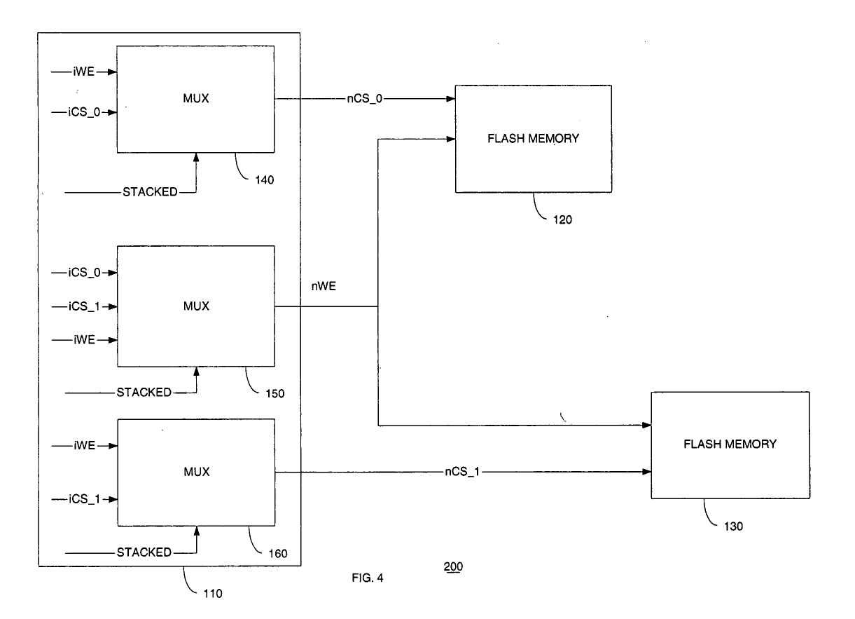

Turning to FIG. 4, shown is a block diagram illustrating an implementation of computing system 200 in accordance with an embodiment of the present invention. For simplicity, the data, address, and output enable signals illustrated in FIG. 3 are not shown in FIG. 4.

FIG. 4 illustrates one implementation of processor 110 to generate signals nCS_0, nCS_1, and nWE. In this implementation, processor 110 may include multiplexers 140, 150, and 160 to generate signals nCS_0, nWE, and nCS_1, respectively. This implementation may be used if the internal write state machine of processor 110 is designed to cause the write to occur on the deassertion of nWE rather than on the deassertion of nCS, i.e., to latch the data and address on the rising edge of nWE. For example, briefly turning to FIG. 5, shown is an example of the internal control signals generated by the internal write state machine, wherein the internal write state machine is designed to cause the write to occur on the deassertion of nWE rather than on the deassertion of nCS.

Multiplexers 140, 150, and 160 may be added to processor 110 to alter or swap the functionality of the CS and WE signals to cause the write to occur on the deassertion of one of the dedicated chip select signals (nCS_0 or nCS_1) rather than on the deassertion of the shared write enable signal. This may be desirable when one of the flash memories is a stacked memory and the other is not. The “i” prefix may indicate that the signal is a signal generated internal to processor 110, e.g., generated by the write state machine of processor 110.

A bit, or several bits, may be used to select the algorithm for transferring or writing data to the flash memories of system 200. For example, a bit may be programmed to enable either latching of the data in a flash memory on the deasserting of the chip select signal or enable latching of the data in a flash memory on the deasserting of the write enable signal.

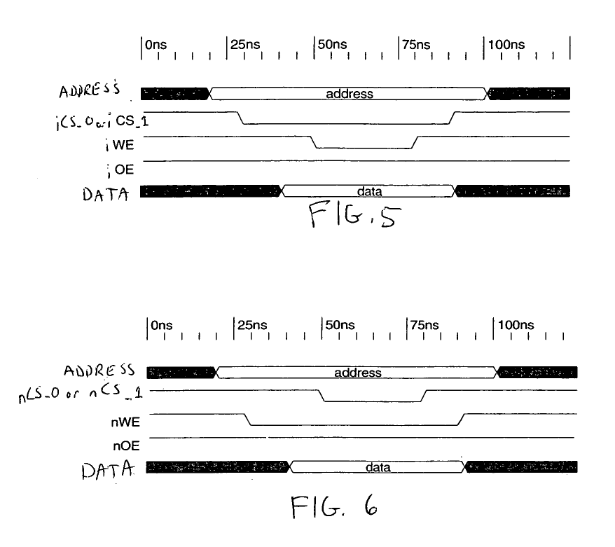

In one embodiment, the bit used may be a bit to indicate whether or not at least one of the flash memories of system 200 is a stacked flash. If set, the bit may indicate that one of the flash memories is stacked, and then this indication may be used as the selection input to multiplexers 140, 150, and 160 to select which of the plurality of internally generated control signals is transferred externally to flash memories 120 and 130. If set, the external control signals may be generated as shown in FIG. 6 based on the internal signals shown in FIG. 5.

Turning to FIG. 7, shown is a block diagram illustrating a wireless device 400 in accordance with an embodiment of the present invention. In one embodiment, wireless device 400 may use the methods discussed above and may include a computing system 410. Computing system 410 may be computing systems 100 or 200 that is discussed above with reference to FIGS. 1-6.

As is shown in FIG. 7, wireless device 400 may include an antenna 420 coupled to a processor of system 410 via a wireless interface 430. In various embodiments, antenna 420 may be a dipole antenna, helical antenna or another antenna adapted to wirelessly communicate information. Wireless interface 430 may be adapted to process radio frequency (RF) and baseband signals using wireless protocols and may include a wireless transceiver.

Wireless device 400 may be a personal digital assistant (PDA), a laptop or portable computer with wireless capability, a web tablet, a wireless telephone (e.g., cordless or cellular phone), a pager, an instant messaging device, a digital music player, a digital camera, or other devices that may be adapted to transmit and/or receive information wirelessly. Wireless device 400 may be used in any of the following systems: a wireless personal area network (WPAN) system, a wireless local area network (WLAN) system, a wireless metropolitan area network (WMAN) system, or a wireless wide area network (WWAN) system such as, for example, a cellular system.

An example of a WLAN system includes a system substantially based on an Industrial Electrical and Electronics Engineers (IEEE) 802.11 standard. An example of a WMAN system includes a system substantially based on an Industrial Electrical and Electronics Engineers (IEEE) 802.16 standard. An example of a WPAN system includes a system substantially based on the Bluetooth™ standard (Bluetooth is a registered trademark of the Bluetooth Special Interest Group). Another example of a WPAN system includes a system substantially based on an Industrial Electrical and Electronics Engineers (IEEE) 802.15 standard such as, for example, the IEEE 802.15.3a specification using ultrawideband (UWB) technology.

Examples of cellular systems include: Code Division Multiple Access (CDMA) cellular radiotelephone communication systems, Global System for Mobile Communications (GSM) cellular radiotelephone systems, Enhanced data for GSM Evolution (EDGE) systems, North American Digital Cellular (NADC) cellular radiotelephone systems, Time Division Multiple Access (TDMA) systems, Extended-TDMA (E-TDMA) cellular radiotelephone systems, GPRS, third generation (3G) systems like Wide-band CDMA (WCDMA), CDMA-2000, Universal Mobile Telecommunications System (UMTS), or the like.

Although computing systems 100 and 200 are illustrated as being used in a wireless device in one embodiment, this is not a limitation of the present invention. In alternate embodiments systems 100 and 200 may be used in non-wireless devices such as, for example, a server, a desktop, or an embedded device not adapted to wirelessly communicate information.

While certain features of the invention have been illustrated and described herein, many modifications, substitutions, changes, and equivalents will now occur to those skilled in the art. It is, therefore, to be understood that the appended claims are intended to cover all such modifications and changes as fall within the true spirit of the invention.

1. A method to write data to a first memory, comprising:
asserting a write enable signal;
asserting a chip enable signal after the asserting of the write enable signal;
deasserting the chip enable signal to latch the data in the first memory, wherein the deasserting of the chip enable signal occurs after the asserting of the write enable signal; and
deasserting the write enable signal after the deasserting of the chip enable signal.

2. The method of claim 1, further comprising:
sending an address to the first memory, wherein the address is the location in the first memory where the data is to be written; and
latching the address and the data in the first memory on the rising or falling edge of the chip enable signal.

3. The method of claim 1, further comprising:
transmitting the write enable signal to the first memory and to a second memory; and
transmitting the chip enable signal to only the first memory.

4. The method of claim 1, further comprising:
sending the write enable signal to at least two memories; and
sending the chip enable signal to only one memory, wherein the one memory is the first memory.

5. The method of claim 1, wherein the chip enable signal is coupled to a chip enable pin of the first memory, the write enable signal is coupled to a write enable pin of the first memory, the write enable signal is coupled to a write enable pin of a second memory, and the chip enable signal is not coupled to a chip enable pin of the second memory.

6. The method of claim 5, wherein the first memory is a nonvolatile memory and the second memory is a nonvolatile memory.

7. The method of claim 6, wherein the first memory is a flash memory and the second memory is a flash memory.

8. The method of claim 5, wherein the first memory is a volatile memory and the second memory is a nonvolatile memory.

9. The method of claim 8, wherein the first memory is a static random access memory (SRAM) or dynamic random access memory (DRAM) and the second memory is a flash memory.

10. The method of claim 1, further comprising:
using a first multiplexer to generate the chip enable signal; and
using a second multiplexer to generate the write enable signal.

11. The method of claim 1, selecting between two signals to generate the chip enable signal.

12. The method of claim 1, programming a bit to enable either latching of the data in the first memory on the deasserting of the chip enable signal or enable latching of the data in the first memory on the deasserting of the write enable signal.

13. A method to transfer data to one of at least two memories, comprising:
latching the data in a first memory of the at least two memories in response to the rising edge or falling edge of a chip select signal.

14. The method of claim 13, wherein the chip select signal is coupled to the first memory and the chip select signal is only coupled to one memory of the at least two memories.

15. The method of claim 13, wherein the chip select signal is coupled to a chip select pin of the first memory of the at least two memories and is not coupled to a chip select pin of a second memory of the at least two memories.

16. The method of claim 13, further comprising:
asserting a write enable signal that is coupled to a write enable pin of the first memory, wherein the write enable signal is coupled to a write enable pin of a second memory of the at least two memories; and
deasserting the chip select signal to latch the data in the first memory, wherein the deasserting of the chip select signal occurs after the asserting of the write enable signal and prior to deasserting of the write enable signal.

17. The method of claim 16, further comprising:
deasserting an output enable signal while the chip select signal is asserted and the write enable signal is asserted;
transmitting the output enable signal to an output enable pin of the first memory; and
transmitting the output enable signal to an output enable pin of the second memory.

18. The method of claim 16, wherein the first memory is a flash memory and the second memory is a flash memory.

19. The method of claim 16, wherein the first memory is a volatile memory and the second memory is a nonvolatile memory.

20. The method of claim 16, wherein the first memory is stacked on a processor and the first memory is located physically closer to the processor than the second memory.

21. A method to transfer data to one of at least two memories, comprising:
deasserting a chip select signal to latch the data in a first memory of the at least two memories, wherein the deasserting of the chip select signal occurs after asserting of a write enable signal and prior to deasserting of the write enable signal.

22. The method of claim 21, further comprising:
deasserting an output enable signal while the chip select signal is asserted and the write enable signal is asserted;
coupling the output enable signal to an output enable pin of the first memory; and
coupling the output enable signal to an output enable pin of a second memory of the at least two memories.

23. The method of claim 21, further comprising:
coupling the write enable signal to a write enable pin of the first memory;
coupling the write enable signal to a write enable pin of a second memory of the at least two memories; and
coupling the chip select signal to a chip select pin of the first memory, wherein the chip select signal is not coupled to a chip select pin of the second memory.

24. The method of claim 23, wherein the first memory is a flash memory and the second memory is a flash memory.

25. The method of claim 23, wherein the first memory is a volatile memory and the second memory is a nonvolatile memory.

26. The method of claim 23, wherein the first memory is stacked on a processor and the first memory is located physically closer to the processor than the second memory.

27. A memory controller to control the writing of data to a first memory and a second memory, comprising;
a circuit to deassert a chip select signal to latch the data in the first memory after asserting a write enable signal and prior to deasserting the write enable signal, wherein the chip select signal is coupled to the first memory and the write enable signal is coupled to both the first memory and the second memory.

28. The memory controller of claim 27, wherein the chip select signal is not coupled to the second memory.

29. The memory controller of claim 27, wherein the chip select signal is coupled to a chip select pin of the first memory, the write enable signal is coupled to a write enable pin of the first memory, the write enable signal is coupled to a write enable pin of the second memory, and the chip select signal is not coupled to a chip select pin of the second memory.

30. The memory controller of claim 27, wherein the circuit comprises:
a first multiplexer to provide the chip select signal to the first memory; and
a second multiplexer to provide the write enable signal to the first memory and the second memory.

31. The memory controller of claim 27, wherein the first memory is a nonvolatile memory and the second memory is a nonvolatile memory.

32. The memory controller of claim 31, wherein the first memory is a flash memory and the second memory is a flash memory.

33. The memory controller of claim 27, wherein the first memory is a volatile memory and the second memory is a nonvolatile memory.

34. The memory controller of claim 33, wherein the first memory is a static random access memory (SRAM) or dynamic random access memory (DRAM) and the second memory is a flash memory.

35. A system, comprising:
a first memory;
a second memory; and
a processor to deassert a chip select signal to latch the data in the first memory after asserting a write enable signal and prior to deasserting the write enable signal, wherein the chip select signal is coupled to the first memory and the write enable signal is coupled to both the first memory and the second memory; and
an antenna coupled to the processor.

36. The system of claim 35, wherein the chip select signal is coupled to a chip select pin of the first memory, the write enable signal is coupled to a write enable pin of the first memory, the write enable signal is coupled to a write enable pin of the second memory, and the chip select signal is not coupled to a chip select pin of the second memory.

37. The system of claim 35, wherein the first memory is located physically closer to the processor than the second memory.

38. The system of claim 35, wherein the first memory is stacked on the processor and the second memory is not stacked on the processor.

39. The system of claim 35, wherein the first memory is a nonvolatile memory and the second memory is a nonvolatile memory.

40. The system of claim 39, wherein the first memory is a flash memory and the second memory is a flash memory.

41. The system of claim 35, wherein the first memory is a volatile memory and the second memory is a nonvolatile memory.

42. The system of claim 41, wherein the first memory is a static random access memory (SRAM) or dynamic random access memory (DRAM) and the second memory is a flash memory.

43. The system of claim 35, wherein the system is a wireless phone.
